(19) United States
(12) Patent Application Publication
(10) Pub. No.: US 2019/0237689 A1
(43) Pub. Date: Aug. 1, 2019

(54) FLEXIBLE DISPLAY SCREEN

(71) Applicant: Yungu (Gu'an) Technology Co., Ltd., Langfang (CN)

(72) Inventors: Huimin LIU, Langfang (CN); Rubo XING, Langfang (CN); Xiaolong YANG, Langfang (CN); Jiantai WANG, Langfang (CN); Dong WEI, Langfang (CN)

(73) Assignee: Yungu (Gu'an) Technology Co., Ltd., Langfang (CN)

(21) Appl. No.: 16/377,440

(22) Filed: Apr. 8, 2019

Related U.S. Application Data
(63) Continuation-in-part of application No. PCT/CN2018/091395, filed on Jun. 15, 2018.

(30) Foreign Application Priority Data
Dec. 29, 2017 (CN) 201711482314.X

(51) Int. Cl. H01L 51/00; H01L 51/52; H01L 51/50

(52) U.S. Cl. CPC H01L 51/0097; H01L 51/5221; H01L 27/3244; H01L 51/5253; H01L 2251/5338; H01L 51/5012

(57) ABSTRACT

The present application provides a flexible display screen including a number of functional film layers stacked in sequence. The functional film layer includes a number of module materials as units constituting the functional film layer, and a gap or a groove is disposed between two adjacent module materials. The groove or the gap can reduce contact area between a functional film layer where the module material is located and another functional film layer disposed adjacent to the functional film layer.

### CROSS-REFERENCE TO ASSOCIATED APPLICATIONS

This application is a Continuation-In-Part application of International Application No. PCT/CN2018/091395, filed on Jun. 15, 2018 which claims priority to CN Patent Application No. 201711482314.X, filed on Dec. 29, 2017. All of the aforementioned applications are hereby incorporated by reference in their entireties.

### TECHNICAL FIELD

Embodiments of the present application relate to the field of display technology, and in particular to a flexible display screen.

### BACKGROUND

At present, a flexible display screen is generally made of a multi-layer film structure. When the flexible display screen is bent, film layer failure is often caused due to stress concentration.

### SUMMARY

In view of the above, the present application provides a flexible display screen, which solves technical problems such as easy delamination between adjacent functional film layers when the flexible display screen is bent.

A flexible display screen according to an embodiment of the present application includes a plurality of functional film layers stacked in sequence, the at least one functional film layer of the plurality of functional film layers includes a plurality of module materials as units constituting the functional film layer, and a gap or a groove is disposed between two adjacent module materials.

In an embodiment of the present application, the gap or the groove is filled with an elastic material.

In an embodiment of the present application, the elastic material has an adhesive property.

In an embodiment of the present application, the elastic material fills up the gap or the groove.

In an embodiment of the present application, the flexible display screen includes a predetermined bend region and the plurality of module materials are located in the predetermined bend region.

In an embodiment of the present application, the gap or the groove has a strip shape, and an extending direction of the strip shape is parallel to a bending axis of the predetermined bend region.

In an embodiment of the present application, the groove is disposed between two adjacent module materials, an opening of the groove facing toward a bending direction of the flexible display screen.

In an embodiment of the present application, the groove is disposed between two adjacent module materials, an opening direction of the groove opposite to a bending direction of the flexible display screen.

In an embodiment of the present application, the plurality of functional film layers include a cathode electrode layer and a display light emitting layer, the cathode electrode layer includes a plurality of electrically connected cathode electrode units as the plurality of module materials, the display light emitting layer includes a plurality of organic light emitting regions, and the cathode electrode unit is disposed in one-to-one correspondence with the organic light emitting region.

In an embodiment of the present application, the organic light emitting regions are distributed in a matrix, the cathode electrode unit is correspondingly disposed on at least one row of the organic light emitting regions, and the at least one row of the organic light emitting regions extends along the bending axis of the predetermined bend region of the flexible display screen.

In the flexible display screen according to embodiments of the present application, by disposing the gap or the groove between two adjacent module materials, contact area between a functional film layer, in which the module material is located, and another functional film layer disposed adjacent to the functional film layer can be reduced. In this case, when the flexible display screen is bent, bending stress generated by a functional film layer, in which the module material is located, and applied to another functional film layer disposed adjacent to the functional film layer is reduced, thereby avoiding separation or fracture between any two adjacent functional film layers when the flexible display screen is bent. Further, by filling the gap or the groove with the elastic material, the gap or the groove can relieve stress concentration and release bending stress when the flexible display screen is bent. Therefore, by providing the groove or the gap filled with the elastic material, defects such as fracture and peeling of the plurality of functional film layers can be avoided, and reliability performance of the flexible display screen can be improved.

### BRIEF DESCRIPTION OF DRAWINGS

FIG. 1 is a schematic structural diagram of a flexible display screen according to an embodiment of the present application.

FIG. 2 is a schematic structural diagram of a flexible display screen according to an embodiment of the present application.

FIG. 3 is a schematic structural diagram of a flexible display screen according to an embodiment of the present application.

### DETAILED DESCRIPTION

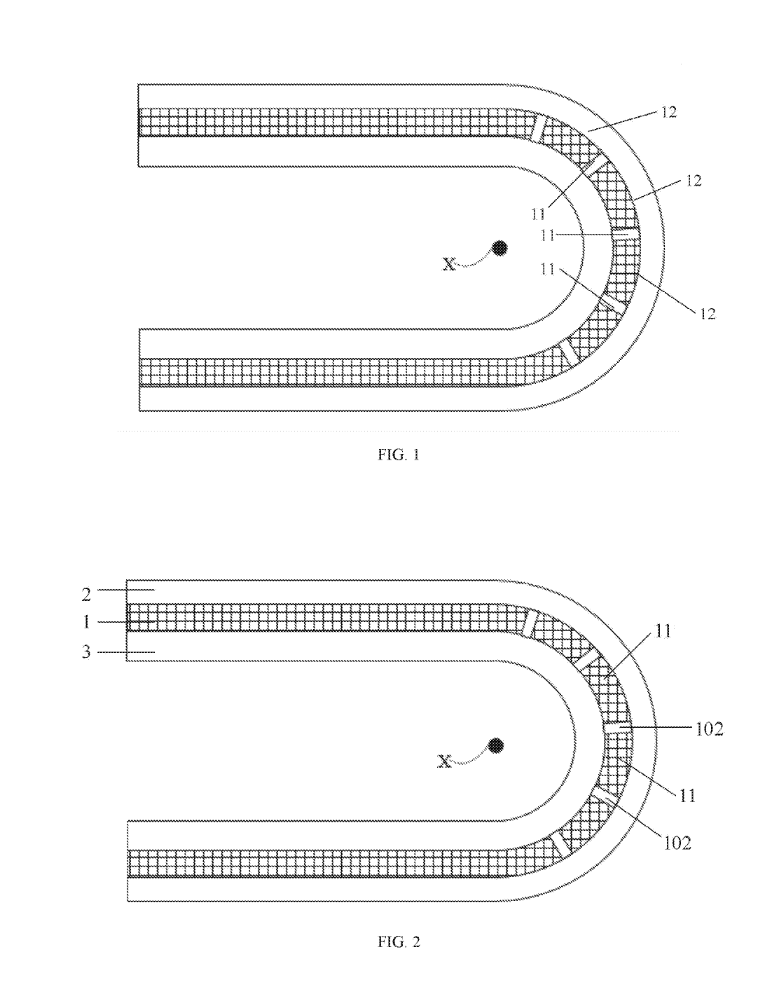

FIG. 1 is a schematic structural diagram of a flexible display screen according to an embodiment of the present application.

As shown in FIG. 1, the flexible display screen may include a plurality of functional film layers stacked in sequence, and the functional film layer may be an organic film layer or an inorganic film layer, which may be understood as a basic film layer constituting the flexible display screen, for example, an anode electrode layer, an organic light emitting layer, a cathode electrode layer, a thin film encapsulation layer, and the like. At least one functional film layer in the plurality of functional film layers includes a plurality of module materials 12, and the module material 12 may be understood as a unit constituting one functional film layer. A gap is disposed between two adjacent module materials 12, and the gap is filled with an elastic material 11. However, it should be understood that a groove may also be disposed between two adjacent module materials 12, and the groove is filled with the elastic material 11. In the embodiment of the present application, the gap or the groove disposed between two adjacent module materials 12 is not specifically limited.

In the flexible display screen according to embodiments of the present application, by disposing the gap or the groove between two adjacent module materials, contact area between a functional film layer, where the module material is located, and another functional film layer disposed adjacent to the functional film layer can be reduced. In that case, when the flexible display screen is bent, bending stress generated by a functional film layer, where the module material is located, and applied to another functional film layer disposed adjacent to the functional film layer is reduced, thereby avoiding separation or fracture between any two adjacent functional film layers when the flexible display screen is bent. Further, by filling the gap or the groove with the elastic material 11, the gap or the groove can relieve stress concentration and release bending stress when the flexible display screen is bent. Therefore, by providing the groove or the gap filled with the elastic material 11, defects such as fracture and peeling of the plurality of functional film layers can be avoided, and reliability performance of the flexible display screen can be improved.

In this way, when the flexible display screen is bent, bending stress generated by the functional film layer where the module material is located and applied to on the adjacent functional film layers is reduced, thereby avoiding separation or fracture between any two adjacent functional film layers. Further, when the flexible display screen is bent, filling the gap or the groove with the elastic material may relieve a stress concentration of the functional film layer where the gap or the groove is located, and release bending stress. A reliability performance of the flexible display screen may be improved.

In an embodiment, the groove is disposed between two adjacent module materials 12, and an opening direction of the groove may face a bending direction of the flexible display screen, or may be opposite to the bending direction of the flexible display screen. In the embodiment of the present application, the opening direction of the groove is not specifically limited. In this case, the bending direction of the flexible display screen may refer to the direction of the curved bulge when the flexible display screen is bent.

In an embodiment, the gap or the groove is disposed between two adjacent module materials 12, and the elastic material 11 may have an adhesive property and may fill up the gaps or the grooves so as to bond the functional film layers on both sides of the plurality of module materials 12. Adhesion performance between the plurality of functional film layers can be improved, thereby avoiding delamination or fracture between the plurality of functional film layers.

In an embodiment, the plurality of functional film layers include a display light emitting layer 3, a cathode electrode layer 1 and a thin film encapsulation layer 2 stacked in sequence, and the thin film encapsulation layer 2 may be mainly used to prevent water vapor and oxygen from immersing into an organic light emitting device, thereby preventing aging of the organic light emitting device and extending the lifetime of the organic light emitting device. The display light emitting layer 3 is used to emit display light. Although the adhesion between the cathode electrode layer 1 and the display light emitting layer 3 is smaller than the adhesion between the cathode electrode layer 1 and the thin film encapsulation layer 2, the elastic material 11 having an adhesive property and filling in the gaps between a plurality of cathode electrode units 102 may bond the display light emitting layer 3 and the thin film encapsulation layer 2, so that the adhesion performance between the display light emitting layer 3, the cathode electrode layer 1, and the thin film encapsulation layer 2 is improved, thereby preventing defects such as separation or peeling between them, and improving the display performance of the flexible display screen.

In an embodiment, the flexible display screen may include a predetermined bend region, and the plurality of module materials 12 may be disposed in the predetermined bend region of the flexible display screen. In this way, the gaps or the grooves can be disposed only in at least one functional film layer in the plurality of functional film layers which are located in the predetermined bend region, and the gaps or the grooves are filled with the elastic material 11, thereby not only simplifying the manufacturing process of the flexible display screen, but also improving the display performance of the flexible display screen.

In an embodiment, the gap or the groove has a strip shape, and the cross-section of the strip-shaped gap or the strip-shaped groove may be rectangular or trapezoidal. The specific shape of the strip-shaped groove is not limited in the embodiment of the present application. An extending direction of the strip shape of the gap or the groove may be parallel to a bending axis X of the predetermined bend region, so that the distance between the strip-shaped gaps or the strip-shaped grooves may become large when the flexible display screen is bent, thereby relieving the bending stress between adjacent module materials 12. However, it should be understood that the extending direction of the strip shape of the gap or the groove may also be perpendicular to the bending axis X of the predetermined bend region, or may have an angle with the bending axis X of the predetermined bend region. The angular relationship between the extending direction of the strip shape of the gap or the groove and the bending axis X of the predetermined bend region is not specifically limited in the embodiment of the present application.

FIG. 2 is a schematic structural diagram of a flexible display screen according to an embodiment of the present application.

Referring to FIG. 2, in an embodiment, the at least one functional film layer includes a cathode electrode layer 1, and the cathode electrode layer 1 includes a plurality of cathode electrode units 102. The gaps between the plurality of cathode electrode units 102 are filled with the elastic material 11, and the elastic material 11 has an adhesive property. Therefore, the elastic material 11 may not only relieve the stress concentration between the plurality of cathode electrode units 102, but also bond the functional film layers on both sides of the plurality of cathode electrode units 102. In the plurality of functional film layers of the flexible display screen, brittleness of the cathode electrode layer 1 is relatively large, and the stress concentration is easily generated on the cathode electrode layer 1 when the flexible display screen is bent. Therefore, the stress concentration on the cathode electrode layer 1 can be effectively relieved by providing the cathode electrode layer 1 as a plurality of electrically connected cathode electrode units 102, thereby avoiding defects such as fracture, separation or peeling between a cathode electrode layer 1 and another functional film layer disposed adjacent to the cathode electrode layer 1. However, it should be understood that the functional film layer of the flexible display screen which is adjacent to the cathode electrode layer 1 may also be made of a structure including the plurality of module materials 12. In the embodiment of the present application, which functional film layer of the flexible display screen is provided as a structure of the plurality of module materials 12 is not specifically limited.

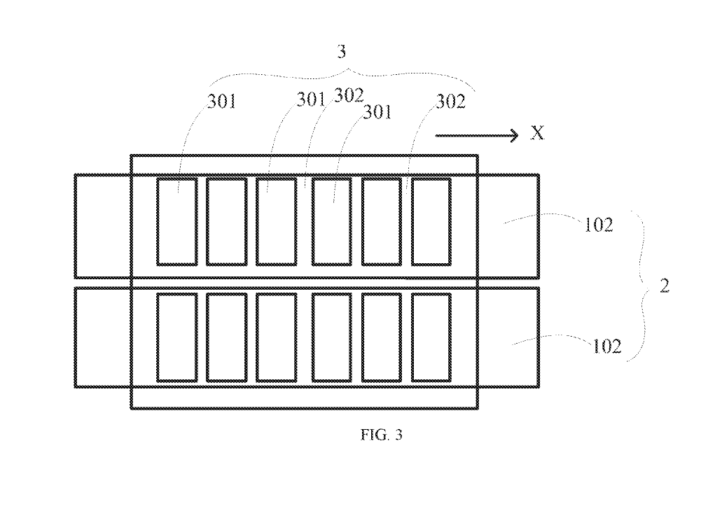

FIG. 3 is a schematic structural diagram of a flexible display screen according to an embodiment of the present application.

Referring to FIG. 3, in an embodiment, the display light emitting layer 3 includes a plurality of organic light emitting regions 301 and a pixel defining region 302 surrounding the plurality of organic light emitting regions 301, and each of the organic light emitting regions 301 corresponds to a light emitting pixel of one color, for example, a red light emitting pixel, a green light emitting pixel or a blue light emitting pixel. However, in the embodiment of the present application, the type of light emitting color of each of the organic light emitting regions 301 is not specifically limited. Each of the cathode electrode units 102 is disposed correspondingly in a light emitting direction of at least one organic light emitting region 301. In this way, a gap between adjacent cathode electrode units 102 can avoid the organic light emitting region 301, thereby not affecting the display performance of the flexible display screen.

However, it should be understood that the cathode electrode unit 102 may also be disposed in one-to-one correspondence with the organic light emitting region 301, so that the stress concentration on the cathode electrode layer 1 can be relieved to the utmost, and defects such as fracture, separation or peeling of a cathode electrode layer 1 and another functional film layer disposed adjacent to the cathode electrode layer 1 can be avoided. Since a pixel defining layer 4 is generally an insulating region, even if the insulating region is not covered by the cathode electrode unit 102, light emitting ability of the flexible display screen cannot be affected. Therefore, in an embodiment of the present application, the cathode electrode unit 102 may not completely cover the pixel defining layer 4, and only the cathode electrode unit 102 and the organic light emitting region 301 are disposed one by one, thereby not affecting the display performance of the flexible display screen.

In an embodiment, the plurality of organic light emitting regions 301 are distributed in a matrix. In this way, not only the display performance of the flexible display screen can be improved, the flexible display screen may be bestrewn with the plurality of organic light emitting regions 301, but also the manufacture of the flexible display screen can be simplified.

In an embodiment, each cathode electrode unit 102 is correspondingly disposed in a light emitting direction of at least one row of the organic light emitting regions 301, and the at least one row of the organic light emitting regions 301 extends along the bending axis X of the predetermined bend region of the flexible display screen. In this way, when the flexible display screen is bent, the bending stress can be relieved by the elastic material 11 located between the plurality of cathode electrode units 102, thereby preventing defects such as separation or peeling between the display layer 3, the cathode electrode layer 1 and the thin film encapsulation layer 2, and improving the display performance of the flexible display screen.

In embodiments of the present application, two adjacent module materials 12 may be discontinuous, that is, there may be a break between the two adjacent module materials 12, and the break is a gap. The two adjacent module materials 12 may be continuous, that is, there may be a long cut between the two adjacent module materials 12, and the cut is a groove.

The above are merely the preferred embodiments of the present application, and are not intended to limit the scope of the present application. Any modifications, equivalent replacements, improvements and the like made within the spirit and principles of the present application should be included in the protection scope of the present application.

What is claimed is:

1. A flexible display screen, comprising a plurality of functional film layers stacked in sequence,
wherein at least one functional film layer in the plurality of functional film layers comprises a plurality of module materials as units constituting the functional film layer, and a gap or a groove is disposed between two adjacent module materials.

2. The flexible display screen according to claim 1, wherein the gap or the groove is filled with an elastic material.

3. The flexible display screen according to claim 2, wherein the elastic material has an adhesive property.

4. The flexible display screen according to claim 2, wherein the elastic material fills up the gap or the groove.

5. The flexible display screen according to claim 1, wherein the flexible display screen comprises a predetermined bend region and the plurality of module materials are located in the predetermined bend region.

6. The flexible display screen according to claim 5, wherein the gap or the groove has a strip shape, and an extending direction of the strip shape is parallel to a bending axis of the predetermined bend region.

7. The flexible display screen according to claim 1, wherein the groove is disposed between two adjacent module materials, an opening of the groove facing toward a bending direction of the flexible display screen.

8. The flexible display screen according to claim 1, wherein the groove is disposed between two adjacent module materials, an opening direction of the groove opposite to a bending direction of the flexible display screen.

9. The flexible display screen according to claim 1, wherein the plurality of functional film layers comprise a cathode electrode layer and a display light emitting layer, the cathode electrode layer comprises a plurality of electrically connected cathode electrode units as the plurality of module materials, the display light emitting layer comprises a plurality of organic light emitting regions, and the cathode electrode unit is disposed in one-to-one correspondence with the organic light emitting region.

10. The flexible display screen according to claim 9, wherein the organic light emitting regions are distributed in a matrix, the cathode electrode unit is correspondingly disposed on at least one row of the organic light emitting regions, and the at least one row of the organic light emitting regions extends along the bending axis of the predetermined bend region of the flexible display screen.
